(19) United States
(12) Patent Application Publication
(10) Pub. No.: US 2019/0222097 A1
(43) Pub. Date: Jul. 18, 2019

(54) PCB-INTEGRATED LEAD MAGNETIC FIELD ENERGY EXTRACTION APPARATUS BASED ON ELECTROMAGNETIC INDUCTION PRINCIPLE

(71) Applicant: Tsinghua University, Beijing (CN)

(72) Inventors: Jun HU, Beijing (CN); Zhongxu WANG, Beijing (CN); Jinliang HE, Beijing (CN); Shanxiang WANG, Beijing (CN)

(21) Appl. No.: 16/321,334

(22) PCT Filed: Jul. 27, 2017
(86) PCT No.: PCT/CN2017/094746

§ 371 Date: Mar. 29, 2019

(30) Foreign Application Priority Data
Jul. 29, 2016 (CN) 201610621072.7

(51) Int. Cl. H02K 7/18; H02K 35/02; H05K 1/18; H01F 27/28

(52) U.S. Cl. CPC H02K 7/18; H01F 27/2804; H05K 1/181; H02K 35/02

(57) ABSTRACT

A PCB-integrated electromagnetic-induction-principle-based power-line magnetic field energy harvester includes a PCB, the PCB including a substrate and a coil; a rotatable permanent magnet assembly, rotatably embedded in the middle through hole; and a fixed permanent magnet arranged opposite the rotatable permanent magnet assembly and providing the rotatable permanent magnet assembly with a direct current bias magnet field. The PCB-integrated electromagnetic-induction-principle-based power-line magnetic field energy harvester is driven by both of the AC magnetic field generated by the power line and the DC bias magnetic field generated by the fixed permanent magnet. The magnetic field energy around the power line is thus converted into the mechanical energy of the rotatable permanent magnet. The mechanical energy is then converted into the electric energy in the coil. The electric energy is supplied to the following low-power electronic devices (e.g. sensors) in a power transmission system.

### FIELD

The present disclosure belongs to the field of energy harvesting, and more particularly, to a PCB-integrated electromagnetic-induction-principle-based power-line magnetic field energy harvester.

### BACKGROUND

Under the background of smart grid becoming a research hotspot, in-depth development has taken place in key matching technologies of various aspects. For the grid, wide area measurement technology for a transmission system has great significance on safety operation, network loss measurement, power flow optimization and fault location. Advanced sensing technology is the basis for the wide area measurement technology of the transmission system. However, sensing applications in current transmission systems mainly focus on indoor occasions like a transformer substation as transmission lines which extend hundreds of kilometers are out of reach of wide area monitoring. The power supply of a sensor is one of the most important reasons why it is difficult to realize the wide-area monitoring and measurement for the transmission system.

With the increasing scale and complexity of the transmission system, a long transmission line span, various types and a large number of online power facilities as well as complicate layouts of distribution networks, it is extremely difficult to install and maintain sensor nodes distributed in a wide area, and furthermore, stricter requirements on a power supply system of the sensor come up.

Currently, energy supply methods for sensors of the power supply system include energy harvesting on a bus of a current transformer (CT) coil, energy harvesting on a bus of a capacitive divider, solar power supply, storage battery power supply and laser light power supply. For the energy harvesting on the bus of the current transformer (CT) coil, the energy harvesting on the bus of the capacitive divider and the storage battery power supply, installation and maintenance are difficult. For the solar power supply and the laser light power supply, they are vulnerable to the environment and expensive.

### SUMMARY

The present disclosure aims at solving one of the above technical problems at least to a certain extent.

Accordingly, the present disclosure provides a PCB-integrated electromagnetic-induction-principle-based power-line magnetic field energy harvester, which adopts a complete non-intrusive design and is easy to mount and dismount, less affected by the environment and high in security.

The PCB-integrated electromagnetic-induction-principle-based power-line magnetic field energy harvester according to embodiments of the present disclosure includes a PCB, the PCB including a substrate and a coil, the substrate containing a middle through hole, and the coil being provided on the substrate and spirally distributed around the middle through hole; a rotatable permanent magnet assembly, the rotatable permanent magnet assembly being rotatably embedded in the middle through hole; and a fixed permanent magnet, the fixed permanent magnets being arranged opposite the rotatable permanent magnet assembly and providing the rotatable permanent magnet assembly with a direct current (DC) bias magnet field.

With the PCB-integrated electromagnetic-induction-principle-based power-line magnetic field energy harvester according to embodiments of the present invention, the rotatable permanent magnet assembly is driven into rotation by means of the magnetic moment between the magnetic field of a power line and the fixed permanent magnet. The magnetic field energy around the power line is thus converted into the mechanical energy of the rotatable permanent magnet. The mechanical energy is then converted into the electric energy in the coil. The electric energy is supplied to the following low-power electronic devices (e.g. sensors) in a power transmission system.

Furthermore, the PCB-integrated electromagnetic-induction-principle-based power-line magnetic field energy harvester according to embodiments of the present invention may have the following additional technical features.

According to an embodiment of the present disclosure, the PCB is provided with a plurality of layers of coils, and the layers of the coils are sequentially arranged in a vertical direction.

According to an embodiment of the present disclosure, the coils on adjacent layers are connected in series or in parallel.

According to an embodiment of the present disclosure, the middle through hole is a square through hole, the rotatable permanent magnet assembly is configured between two opposite side walls of the square through hole.

According to an embodiment of the present disclosure, the power line magnetic field energy harvester further includes two fixing parts, the two fixing parts are provided on opposite side walls of the square through hole, each of the two fixing parts contains a first positioning hole, and a shaft of the rotatable permanent magnet assembly extends into the first positioning hole.

According to an embodiment of the present disclosure, the rotatable permanent magnet assembly includes a rotatable permanent magnet, the rotatable permanent magnet contains a second positioning hole in a side opposite the fixing part, a first end of the shaft extending into the first positioning hole and a second end of the shaft extending into the second positioning hole; and a bearing, the bearing being press-fitted in the first positioning hole, an inner ring of the bearing fitted with an outer circumferential surface of the shaft, and an outer ring of the bearing fitted with an inner circumferential surface of the first positioning hole.

According to an embodiment of the present disclosure, the fixing parts, the bearing and the shaft are magnetically insulated.

According to an embodiment of the present disclosure, the power line magnetic field energy harvester further includes a case, the PCB is arranged in the case, and the fixed permanent magnets is provided on the PCB.

According to an embodiment of the present disclosure, the fixed permanent magnet includes two bar-shaped permanent magnets, the two bar-shaped permanent magnets are arranged on two opposite sides of the PCB.

According to an embodiment of the present disclosure, the fixed permanent magnet includes two bar-shaped permanent magnets, the two bar-shaped permanent magnets are arranged on two opposite sides of the PCB, extending directions of the two bar-shaped permanent magnets are parallel to an axis of the rotatable permanent magnet assembly, and an axial direction of the rotatable permanent magnet assembly is the same as an extending direction of the power line.

According to an embodiment of the present disclosure, the rotatable permanent magnet is in clearance fit with the square through hole.

Additional aspects and advantages of the present disclosure will be given in the following description, some of which will become apparent from the following description or be learned from practices of the present disclosure.

### BRIEF DESCRIPTION OF THE DRAWINGS

The above and/or additional aspects and advantages of the present disclosure will become apparent and easy to understand from descriptions of the embodiments with reference to the drawings, in which:

FIG. 1 is a schematic view illustrating a PCB-integrated electromagnetic-induction-principle-based power-line magnetic field energy harvester according to an embodiment of the present disclosure.

### REFERENCE SIGNS

printed circuit board (PCB) 10; substrate 11; middle through hole 111; coil 12; rotatable permanent magnet assembly 20; shaft 21; rotatable permanent magnet 22; bearing 23; fixed permanent magnet 30; fixing part 40; power line 200.

### DETAILED DESCRIPTION

Embodiments of the present disclosure are described below in detail, examples of the embodiments are shown in accompanying drawings, and reference signs that are the same or similar from beginning to end represent the same or similar assemblies or assemblies that have the same or similar functions. The embodiments described below with reference to the accompanying drawings are exemplary, are merely used to explain the present disclosure, and cannot be construed as a limit to the present disclosure

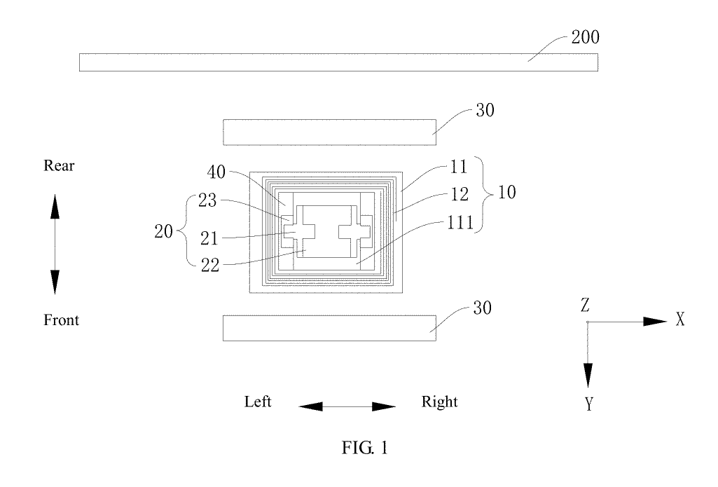

A PCB-integrated electromagnetic-induction-principle-based power-line magnetic field energy harvester according to an embodiment of the present disclosure will be described hereafter with reference to FIG. 1. The power line magnetic field energy harvester is arranged adjacent to a power line 200 of a transmission system and configured to collect magnetic field energy in the power line 200, and the magnetic field energy is converted into the mechanical energy and then is converted into electric energy. The electric energy is supplied to the following low-power electronic devices (e.g. sensors) in a power transmission system.

A PCB-integrated electromagnetic-induction-principle-based power-line magnetic field energy harvester according to embodiments of the present disclosure generally includes a PCB 10, a rotatable permanent magnet assembly 20 and a fixed permanent magnet 30.

Specifically, as shown in FIG. 1, the PCB 10 includes a substrate 11 and a coil 12, the substrate 11 contains a middle through hole 111, and the coil 12 is provided on the substrate 11 and spirally distributed around the middle through hole 111. The rotatable permanent magnet assembly 20 is rotatably embedded in the middle through hole 111. The fixed permanent magnet 30 is arranged opposite the rotatable permanent magnet assembly 20 and provides the rotatable permanent magnet assembly 20 with a direct current (DC) bias magnet field. The coil 12 may be spirally distributed on the substrate 11 from the inside out, or the coil 12 may be spirally distributed on the substrate 11 from outside to inside. The inside and the outside are relative to a central position of the middle through hole 111, an end of the coil 12 adjacent to a central axis of the middle through hole 111 is defined as an inside end while an end of the coil 12 away from the central axis of the middle through hole 111 is defined as an outside end. With the magnetic moment coupling between the magnetic field generated by the power line 200 and the fixed permanent magnet 30, the rotatable permanent magnet 22 is driven to rotate for a vast scale and collects energy through the coil 12 on the substrate 11. In other words, under an action of the magnetic moment between the magnetic field generated by the power line 200 and the fixed permanent magnet 30, the rotatable permanent magnet 22 rotates in the middle through hole 111, which brings changes to magnetic flux of the coil 12 and further generates a current in the coil 12. An output end of the power line magnetic field energy harvester is connected to a sensor and arranged adjacent to the power line 200.

With the PCB-integrated electromagnetic-induction-principle-based power-line magnetic field energy harvester according to an embodiment of the present disclosure, the rotatable permanent magnet assembly 20 is driven to rotate by means of the magnetic moment between the magnetic field of a power line 200 and the fixed permanent magnet 30. The magnetic field energy around the power line 200 is converted into the mechanical energy of the rotatable permanent magnet 22. The mechanical energy is then converted into electric energy in the coil 12. The electric energy is supplied to the following low-power electronic devices (e.g. sensors) in a power transmission system.

The method for extracting energy through placing the rotatable permanent magnet 22 in the coil 12 can not only greatly enhance the coupling between the coil 12 and an external magnetic field, but also save the power line magnetic field energy harvester from being arranged around the coil 200. While lowering the level of difficulty of installation, such a flexible arrangement also makes it possible to miniaturize and reduce the cost of the power line magnetic field energy harvester.

Compared with an energy harvesting method based on a current transformer, a Rogowski coil or a capacitance divider, the PCB-integrated electromagnetic-induction-principle-based power-line magnetic field energy harvester according to embodiments of the present disclosure adopts a complete non-intrusive design that is easy to mount and dismount, which brings great facility to project implementation and maintenance.

Characterized in a small size and low cost, the whole power line magnetic field energy harvester does not depend upon external environmental factors like weather or geographical location and is not susceptible to bad weather.

During operation, since the PCB-integrated power line 200 magnetic field energy harvester 100 based on an electromagnetic induction principle according to embodiments of the present disclosure converts the mechanical energy converted from the magnetic field energy into electric energy and only a small portion of the magnetic field energy is directly converted into electric energy, the safety performance is greatly improved compared with the currently widely-used current transformer that directly converts the magnetic field energy into electric energy. The output energy is almost irrelevant to the rate of change of the electric field intensity. Therefore, under the circumstance of an abrupt change of a current, a secondary electronic circuit will not be damaged due to a high voltage in a transient state. Besides, since the power line magnetic field energy harvester is restricted by the confinement magnetic field of the fixed permanent magnet 30 during operation, the rotatable permanent magnet 22 has a limited rotation limit angle and rotation speed, such that in the case of a short circuit fault, the electric circuit will not be damaged by an excessive output voltage.

In some embodiments of the present disclosure, the PCB 10 is provided with a plurality of layers of coils 12, and the layers of coils 12 are sequentially arranged in a vertical direction. In other words, the PCB 10 is integrated with a plurality of layers of coils 12, which greatly improves the density of the coils 12. During rotation, the rotatable permanent magnet assembly 20 may change the magnetic flux in the plurality of layers of coils 12 simultaneously and thus generating electric energy in the plurality of layers of coils 12 at the same time, which increases the power density of the power line magnetic field energy harvester. Moreover, integrations of the PCB and sensors are unified with a rather high integration degree. An insulation layer is provided between the coils 12 on adjacent layers, thereby preventing a short circuit between the coils 12.

Alternatively, the coils 12 on adjacent layers are connected in series. For a better illustration, assuming that there are three layers of the coils 12 sequentially arranged in a vertical direction, the coil 12 on a top layer is spirally distributed on the substrate 11 from the inside out, and a beginning end of the coil 12 on the top layer is at an inner side of the substrate 11 and a tail end of the coil 12 on the top layer is at an outer side of the substrate 11. The coil on a middle layer is spirally distributed on the substrate 11 from outside to inside, and a beginning end of the coil on the middle layer is at the outer side of the substrate 11 and a tail end of the coil on the middle layer is at the inner side of the substrate 11. The coil 12 on a bottom layer is spirally distributed on the substrate 11 from the inside out, and a beginning end of the coil 12 on the bottom layer is at the inner side of the substrate 11 and a tail end of the coil 12 on the bottom layer is at the outer side of the substrate 11. The tail end of the coil 12 on the top layer is connected to the beginning end of the coil on the middle layer, and the tail end of the coil on the middle layer is connected to the beginning end of the coil 12 on the bottom layer, such that the coils 12 at the three layers are connected in series. The beginning end of the coil 12 on the top layer and the tail end of the coil 12 on the bottom layer form output ends of the power line magnetic field energy harvester and the output ends are connected to electronic devices like a sensor, and thus transmitting the electric energy generated by the three layers of the coils 12.

When the coils 12 on adjacent layers are connected in series, spiral directions of the coils 12 on adjacent layers are opposite to each other to avoid a reciprocal reduction on electromotive forces of the coils 12 on adjacent layers. For instance, the coil 12 on the top layer is distributed on the substrate 11 from the inside out in a counterclockwise direction, the coil 12 on the middle layer is distributed on the substrate 11 from the inside out in a clockwise direction, and the coil 12 on the bottom layer is distributed on the substrate 11 from the inside out in a counterclockwise direction.

Alternatively, the coils 12 on adjacent layers may also be connected in parallel. For a better illustration, assuming that there are three layers of the coils 12 sequentially arranged in a vertical direction, the coil 12 on the top layer is spirally distributed on the substrate 11 from the inside out, a beginning end of the coil 12 on the top layer is at the inner side of the substrate 11 and a tail end of the coil 12 on the top layer is at the outer side of the substrate 11. The coil on the middle layer is spirally distributed on the substrate 11 from the inside out, a beginning end of the coil on the middle layer is at the inner side of the substrate 11, and a tail end of the coil on the middle layer is at the outer side of the substrate 11. The coil on the bottom layer is spirally distributed on the substrate 11 from the inside out, a beginning end of the coil on the bottom layer is at the inner side of the substrate 11, and a tail end of the coil on the bottom layer is at the outer side of the substrate 11. Beginning ends of the coil 12 on the top layer, the coil on the middle layer and the coil on the bottom layer are connected together and tail ends of the coil 12 on the top layer, the coil on the middle layer and the coil on the bottom layer are connected together, such that the coils 12 at the three layers are connected in parallel. The beginning and tail ends of the coil 12 on the top layer or the coil on the bottom layer may act as output ends of the power line magnetic field energy harvester and be connected to electronic devices like a sensor, and thus transmitting the electric energy generated by the three layers of the coils 12.

When the coils 12 on adjacent layers are connected in parallel, spiral directions of the coils 12 on adjacent layers are identical to each other to avoid a reciprocal reduction on electromotive forces of the coils 12 on adjacent layers. For instance, the coil 12 on the top layer is distributed on the substrate 11 from the inside out in a counterclockwise direction, the coil 12 on the middle layer is distributed on the substrate 11 from the inside out in a counterclockwise direction, and the coil 12 on the bottom layer is distributed on the substrate 11 from the inside out in a counterclockwise direction.

It should be understood that the embodiments described above are exemplary and cannot be construed as a limit to the embodiments of the present disclosure. Two or four or more layers of the coils 12 may be arranged on the PCB 10. The PCB technology should be understood by a person skilled in the art and will not be detailed herein.

In some further embodiments of the present disclosure, the middle through hole 11 is a square through hole, the rotatable permanent magnet assembly 20 is configured between two opposite side walls of the square through hole.

Furthermore, the power line magnetic field energy harvester further includes two fixing parts 40, the two fixing parts 40 are provided on opposite side walls of the square through hole, each of the two fixing parts 40 contains a first positioning hole, and a shaft 21 of the rotatable permanent magnet assembly 20 extends into the first positioning hole. As shown in FIG. 1, one side of the fixing part 40 is connected to the side wall of the square through hole and the other side of the fixing part 40 extends towards the direction of the core of the square through hole. The first positioning hole is defined by that the other side of the fixing part 40 recesses toward the one side of the fixing part 40, an axial direction of the shaft 21 of the rotatable permanent magnet assembly 20 is identical to an extending direction of the first positioning hole.

In a specific embodiment of the present disclosure, the rotatable permanent magnet assembly 20 includes a bearing 23 and a rotatable permanent magnet 22.

The rotatable permanent magnet 22 contains a second positioning hole in a side (the left or right side of the rotatable permanent magnet 22 as shown in FIG. 1) opposite the fixing part 40, one end of the shaft 21 extends into the first positioning hole and the other end of the shaft 21 extends into the second positioning hole. In other words, the shaft 21 is provided between the rotatable permanent magnet 22 and each of the fixing parts 40, one end of each shaft 21 is press-fitted in the first positioning hole, and the other end of each shaft 21 is press-fitted in the second positioning hole.

The bearing 23 is press-fitted in the first positioning hole, an inner ring of the bearing 23 is fitted with an outer circumferential surface of the shaft 21, and an outer ring of the bearing 23 is fitted with an inner circumferential surface of the first positioning hole. Through providing the bearing 23 in the first positioning hole, the shaft 21 may rotate more smoothly with a small friction resistance, thus the rotatable permanent magnet assembly 20 may be driven into rotation with a small driving force.

The fixing part 40, the bearing 23 and the shaft 21 are magnetically insulated. For example, the shaft 21 may be made of copper or aluminum materials and the bearing 23 may be a ceramic bearing. Therefore, the magnetic field generated by the power line 200 and the fixed permanent magnet 30 may be prevented from acting on the fixing part 40, the bearing 23 and the shaft 21, thereby preventing the rotation of the rotatable permanent magnet assembly 20 from being disturbed.

Alternatively, the rotatable permanent magnet 22 is in clearance fit with the square through hole. Therefore, it may be guaranteed that the rotatable permanent magnet 22 rotates smoothly in the square through hole under the action of the magnetic field force and generates a current in the coil 12.

In yet other embodiments of the present disclosure, the power line magnetic field energy harvester further includes a case (not shown), the PCB 10 is arranged in the case, and the fixed permanent magnet 30 is arranged on the PCB 10. That is to say, both the PCB 10 and the rotatable permanent magnet assembly 20 arranged in the square through hole of the PCB 10 are provided in the case, and PCB 10 contains an accommodating groove fitted with the fixed permanent magnet 30. It should be understood that the fixed permanent magnet 30 may also be arranged separately from the PCB 10, i.e., the fixed permanent magnet 30 and the PCB 10 are respectively arranged in the case and the fixed permanent magnet 30 is arranged opposite the rotatable permanent magnet assembly 20, thereby providing the rotatable permanent magnet assembly 20 with a DC bias magnet field.

Alternatively, as shown in FIG. 1, the fixed permanent magnet 30 includes two bar-shaped permanent magnets, the two bar-shaped permanent magnets are arranged on two opposite sides of the PCB 10. Extending directions of the two bar-shaped permanent magnets are parallel to the axis of the rotatable permanent magnet assembly 20, and the axial direction of the rotatable permanent magnet assembly 20 (extending along an X-axis direction as shown in FIG. 1) is the same as an extending direction of the power line 200. A direction of the magnetic field generated by the power line 200 is the same as a Z-axis direction as shown in FIG. 1, and a magnetizing direction of the bar-shaped permanent magnets is identical to a Y-axis direction as shown in FIG. 1. Therefore, with the magnetic moment coupling between the magnetic field generated by the power line 200 and the fixed permanent magnet 30, the rotatable permanent magnet 22 may be driven to rotate for a vast scale and collect energy through the coil 12 on the substrate 11, thereby providing electric energy for sensors and other electronic devices.

In the description of the present disclosure, it is to be understood that, terms such as “up”, “down”, “bottom”, “inside”, “outside”, “horizontal”, “axial” refer to the directions and location relations which are the directions and location relations shown in the drawings, and for describing the present disclosure and for describing in simple, and which are not intended to indicate or imply that the device or the elements are disposed to locate at the specific directions or are structured and performed in the specific directions, which could not to be understood to the limitation of the present disclosure.

In addition, terms such as “first” and “second” are used herein for purposes of description and are not intended to indicate or imply relative importance or significance. Furthermore, the feature defined with “first” and “second” may comprise one or more this feature distinctly or implicitly. In the description of the present disclosure, the term “a plurality of” means two or more than two, unless specified otherwise.

In the present disclosure, unless specified or limited otherwise, the terms “mounted,” “connected,” “coupled” and “fixed” are understood broadly, such as fixed, detachable mountings, connections and couplings or integrated, and can be mechanical or electrical mountings, connections and couplings, and also can be direct and via media indirect mountings, connections, and couplings, and further can be inner mountings, connections and couplings of two assemblies, which can be understood by those skilled in the art according to the detail embodiment of the present disclosure.

In the present disclosure, unless specified or limited otherwise, the first characteristic being “on” or “under” the second characteristic refers to the first characteristic and the second characteristic can be direct or via other characteristics thereof indirect mountings, connections, and couplings. And, the first characteristic being “on”, “above”, “over” the second characteristic may refer to the first characteristic is right over the second characteristic or is diagonal above the second characteristic, or just refer to the horizontal height of the first characteristic is higher than the horizontal height of the second characteristic. The first characteristic is “below” or “under” the second characteristic may refer to the first characteristic is right under the second characteristic or is diagonal under the second characteristic, or just refer to the horizontal height of the first characteristic is lower than the horizontal height of the second characteristic.

In the description of the present disclosure, reference throughout this specification to “an embodiment,” “some embodiments,” “an example,” “a specific example,” or “some examples,” means that a particular feature, structure, material, or characteristic described in connection with the embodiment or example is included in at least one embodiment or example of the present disclosure. Thus, the appearances of the phrases in various places throughout this specification are not necessarily referring to the same embodiment or example of the present disclosure. Furthermore, the particular features, structures, materials, or characteristics may be combined in any suitable manner in one or more embodiments or examples.

Although embodiments of present disclosure have been shown and described above, it should be understood that above embodiments are just explanatory, and cannot be construed to limit the present disclosure, for those skilled in the art, changes, alternatives, and modifications can be made to the embodiments without departing from spirit, principles, and scope of the present disclosure.

1. A printed circuit board (PCB)-integrated electromagnetic-induction-principle-based power-line magnetic field energy harvester comprising:
a PCB, the PCB comprising:
a substrate containing a middle through hole; and
a coil provided on the substrate and spirally distributed around the middle through hole;
a rotatable permanent magnet assembly rotatably embedded in the middle through hole;
a fixed permanent magnet arranged opposite the rotatable permanent magnet assembly and providing the rotatable permanent magnet assembly with a direct current (DC) bias magnet field.

2. The PCB-integrated electromagnetic-induction-principle-based power-line magnetic field energy harvester according to claim 1, wherein the PCB is provided with a plurality of layers of coils, and the layers of the coils are sequentially arranged in a vertical direction.

3. The PCB-integrated electromagnetic-induction-principle-based power-line magnetic field energy harvester according to claim 2, wherein the coils on adjacent layers are connected in series or in parallel.

4. The PCB-integrated electromagnetic-induction-principle-based power-line magnetic field energy harvester according to claim 1, wherein the middle through hole is a square through hole, the rotatable permanent magnet assembly is configured between two opposite side walls of the square through hole.

5. The PCB-integrated electromagnetic-induction-principle-based power-line magnetic field energy harvester according to claim 4, wherein the power line magnetic field energy harvester further comprises two fixing parts, the two fixing parts are provided on opposite side walls of the square through hole, each of the two fixing parts contains a first positioning hole, and a shaft of the rotatable permanent magnet assembly extends into the first positioning hole.

6. The PCB-integrated electromagnetic-induction-principle-based power-line magnetic field energy harvester according to claim 5, wherein the rotatable permanent magnet assembly comprises:
a rotatable permanent magnet, the rotatable permanent magnet contains a second positioning hole in a side opposite the fixing part, a first end of the shaft extending into the first positioning hole and a second end of the shaft extending into the second positioning hole; and
a bearing, the bearing being press-fitted in the first positioning hole, an inner ring of the bearing fitted with an outer circumferential surface of the shaft, and an outer ring of the bearing fitted with an inner circumferential surface of the first positioning hole.

7. The PCB-integrated electromagnetic-induction-principle-based power-line magnetic field energy harvester according to claim 6, wherein the fixing parts, the bearing and the shaft are magnetically insulated.

8. The PCB-integrated electromagnetic-induction-principle-based power-line magnetic field energy harvester according to claim 1, further comprising a case, the PCB being arranged in the case, and the fixed permanent magnets being provided on the PCB.

9. The PCB-integrated electromagnetic-induction-principle-based power-line magnetic field energy harvester according to claim 8, wherein the fixed permanent magnet includes two bar-shaped permanent magnets, the two bar-shaped permanent magnets are arranged on two opposite sides of the PCB, extending directions of the two bar-shaped permanent magnets are parallel to an axis of the rotatable permanent magnet assembly, and an axial direction of the rotatable permanent magnet assembly is the same as an extending direction of the power line.

10. The PCB-integrated electromagnetic-induction-principle-based power-line magnetic field energy harvester according to claim 6, wherein the rotatable permanent magnet is in clearance fit with the square through hole.

11. The PCB-integrated electromagnetic-based power-line magnetic field energy harvester according to claim 2, further comprising a case, the PCB being arranged in the case, and the fixed permanent magnets being provided on the PCB.

12. The PCB-integrated electromagnetic-based power-line magnetic field energy harvester according to claim 3, further comprising a case, the PCB being arranged in the case, and the fixed permanent magnets being provided on the PCB.

13. The PCB-integrated electromagnetic-based power-line magnetic field energy harvester according to claim 4, further comprising a case, the PCB being arranged in the case, and the fixed permanent magnets being provided on the PCB.

14. The PCB-integrated electromagnetic-based power-line magnetic field energy harvester according to claim 5, further comprising a case, the PCB being arranged in the case, and the fixed permanent magnets being provided on the PCB.

15. The PCB-integrated electromagnetic-based power-line magnetic field energy harvester according to claim 6, further comprising a case, the PCB being arranged in the case, and the fixed permanent magnets being provided on the PCB.

16. The PCB-integrated electromagnetic-based power-line magnetic field energy harvester according to claim 7, further comprising a case, the PCB being arranged in the case, and the fixed permanent magnets being provided on the PCB.

17. The PCB-integrated electromagnetic-based power-line magnetic field energy harvester according to claim 11, wherein the fixed permanent magnet includes two bar-shaped permanent magnets, the two bar-shaped permanent magnets are arranged on two opposite sides of the PCB, extending directions of the two bar-shaped permanent magnets are parallel to an axis of the rotatable permanent magnet assembly, and an axial direction of the rotatable permanent magnet assembly is the same as an extending direction of the power line.

18. The PCB-integrated electromagnetic-based power-line magnetic field energy harvester according to claim 12, wherein the fixed permanent magnet includes two bar-shaped permanent magnets, the two bar-shaped permanent magnets are arranged on two opposite sides of the PCB, extending directions of the two bar-shaped permanent magnets are parallel to an axis of the rotatable permanent magnet assembly, and an axial direction of the rotatable permanent magnet assembly is the same as an extending direction of the power line.

19. The PCB-integrated electromagnetic-based power-line magnetic field energy harvester according to claim 13, wherein the fixed permanent magnet includes two bar-shaped permanent magnets, the two bar-shaped permanent magnets are arranged on two opposite sides of the PCB, extending directions of the two bar-shaped permanent magnets are parallel to an axis of the rotatable permanent magnet assembly, and an axial direction of the rotatable permanent magnet assembly is the same as an extending direction of the power line.

20. The PCB-integrated electromagnetic-based power-line magnetic field energy harvester according to claim 14, wherein the fixed permanent magnet includes two bar-shaped permanent magnets, the two bar-shaped permanent magnets are arranged on two opposite sides of the PCB, extending directions of the two bar-shaped permanent magnets are parallel to an axis of the rotatable permanent magnet assembly, and an axial direction of the rotatable permanent magnet assembly is the same as an extending direction of the power line.
